(19) United States
(12) Patent Application Publication
(10) Pub. No.: US 2026/0136471 A1
(43) Pub. Date: May 14, 2026

(54) Circuit and Fuse Fabrication Process for Flexible Printed Circuit Board (FPCB)

(71) Applicant: GUANGZHOU AMPHENOL SINCERE FLEX CIRCUITS CO., LTD, Guangzhou (CN)

(72) Inventors: Jiawen CHEN, Guangzhou (CN); Jian WANG, Guangzhou (CN); Fan ZHENG, Guangzhou (CN); Gaixian SUN, Guangzhou (CN); Xiaoming WU, Guangzhou (CN)

(73) Assignee: GUANGZHOU AMPHENOL SINCERE FLEX CIRCUITS CO., LTD, Guangzhou (CN)

(21) Appl. No.: 19/021,313

(22) Filed: Jan. 15, 2025

(30) Foreign Application Priority Data
Nov. 14, 2024 (CN) 202411621883.8

(51) Int. Cl. H05K 3/04; H05K 1/03; H05K 1/16

(52) U.S. Cl. CPC H05K 3/041; H05K 1/0306; H05K 1/16; H05K 2201/05; H05K 2201/10181; H05K 2203/0228; H05K 2203/0235

(57) ABSTRACT

The provided is a circuit and fuse fabrication process for a flexible printed circuit board (FPCB). The circuit and fuse fabrication process includes: pressing and bonding a release film onto a bottom of a polyethylene terephthalate (PET) silicone film; removing the release film at a circuit and fuse alignment position at the bottom of the PET silicone film through a lower circular knife die, and retaining the release film located outside the circuit and fuse alignment position; aligning the position of the PET silicone film; pressing and bonding the metal foil onto the PET silicone film with a release film side; cutting to form the circuit and the fuse; bonding a PET silicone film onto a bottom of the metal foil; removing the PET silicone film and a metal foil waste; and retaining the circuit and fuse formed by cutting on the PET silicone film with the release film side.

### CROSS-REFERENCE TO THE RELATED APPLICATIONS

This application is based upon and claims priority to Chinese Patent Application No. 202411621883.8, filed on Nov. 14, 2024, the entire contents of which are incorporated herein by reference.

### TECHNICAL FIELD

The present disclosure relates to the field of flexible printed circuit board (FPCB) processing, and in particular to a circuit and fuse fabrication process for an FPCB.

### BACKGROUND

With the development of modern society, car charging piles can be seen everywhere in China. The explosive growth in the sales of new energy vehicles (NEVs) has driven domestic demand and increased foreign exchange. Due to battery range issues, flexible printed circuit boards (FPCBs) are used to replace most of the wiring harnesses to increase battery capacity, thereby improving battery range. Currently, the circuit and fuse fabrication of the FPCB mainly includes the following steps. A metal foil 2 is directly bonded to the bottom of a polyethylene terephthalate (PET) silicone film 1, and a circuit and a fuse 4 are formed by cutting with a die. A PET silicone film 3 is bonded onto the bottom of the metal foil. The PET silicone film at the bottom of the metal foil and a metal foil waste are removed. The circuit and fuse formed by cutting are retained on the PET silicone film above the metal foil, as shown in FIG. 1. However, due to the PET silicone film bonded directly onto the bottom of the metal foil, the retained circuit and fuse are in the same plane as the metal foil waste. When the PET silicone film at the bottom of the metal foil and the metal foil waste are removed, the fine and flexible circuit and fuse are easily pulled up or down by the removal force. As a result, the fine and flexible circuit and the fuse on the metal foil are prone to problems such as misalignment and deformation, thereby affecting the yield of the FPCB product. Even if the waste is slowly peeled off, it is also difficult to improve the yield rate, and there will be a decrease in production efficiency.

Particularly when the fuse is fabricated on the metal foil, in order to ensure that the fuse can disconnect the circuit in the event of a high current, the thickness and line width of the fuse need to be very small. However, fuses with very small thickness and line width are more prone to misalignment and deformation due to the pulling up or down by the removal force.

### SUMMARY

An objective of the present disclosure is to provide a circuit and fuse fabrication process for a flexible printed circuit board (FPCB), solving the problems of misalignment and deformation of a circuit and a fuse on a metal foil and improving the yield of the FPCB product.

The present disclosure provides a circuit and fuse fabrication process for the FPCB, including the following steps:
S1: pressing and bonding, by an upper rubber roller and a lower steel roller, a release film featuring an original film with a thickness of 0.02-0.08 mm, a release adhesive with a thickness of 0.001-0.005 mm, and a peeling force of 1-10 G onto a bottom of a polyethylene terephthalate (PET) silicone film featuring an original film with a thickness of 0.06-0.08 mm, an adhesive with a thickness of 0.01-0.03 mm, and a peeling force of 600-1,000 G;
S2: removing, based on a position to retain a circuit and a fuse on a metal foil with a thickness of 0.03-0.12 mm, the release film at a circuit and fuse alignment position at the bottom of the PET silicone film through a lower circular knife die, where a width of the removed release film is 0.1-0.2 mm larger than a width of the circuit and the fuse; and retaining the release film located outside the circuit and fuse alignment position;
S3: aligning, based on the position to retain the circuit and the fuse on the metal foil, the position of the PET silicone film where the release film is removed; pressing and bonding, by the upper rubber roller and the lower steel roller, the metal foil onto a release film side of the PET silicone film; and cutting, by a lower circular knife die, to form a circuit and a curved fuse; and
S4: bonding a PET silicone film onto a bottom of the metal foil after cutting to form the circuit and the fuse; removing the PET silicone film at the bottom of the metal foil and a metal foil waste; and retaining the circuit and fuse formed by cutting on the release film side of the PET silicone film.

The fuse includes a bead-shaped fuse and/or a curved fuse; the bead-shaped fuse is formed by bead-shaped metal foils that are connected in series; a connecting line of each of the bead-shaped metal foils has a line width of 0.12-0.18 mm; and the curved fuse has a line width of 0.12-0.18 mm.

However, the fuse is not limited to the above two types, and other fuses with a line width of 0.12-0.18 mm are within the scope of protection of the present disclosure.

In the above process, the original film thickness, adhesive thickness, and peeling force of PET silicone film, the original film thickness and release adhesive thickness of the release film, and the width of the removed release film will all significantly affect the yield.

The original film of the PET silicone film mainly plays a supporting role, and if its thickness is too small, it will cause insufficient support.

The adhesive of the PET silicone film mainly plays a bonding role in the process of cutting the release film and the metal circuit, and also plays a buffering role. If the adhesive is too thin, it is easy to damage the original film during the cutting process. If the adhesive is too thick, it can easily cause slight vertical movement of the metal foil during the cutting process, which may result in a decrease in the yield.

An appropriate adhesive peeling force of the PET silicone film will prevent the release film and the metal foil from sliding during the cutting process, and prevent the conductive circuit and the fuse from being misaligned, deformed, or even damaged during the peeling process.

The thickness of the release film is mainly related to the thickness of the metal foil. The sum of the original film thickness of the release film and the thickness of the release adhesive is less than the thickness of the metal foil. In this way, the metal foil can be recessed into the film and bonded with the high-viscosity PET silicone film after rolling, and form a staggered structure after circuit cutting, avoiding damage during the process of peeling off the waste.

In the step S2, the width of the removed release film is 0.1-0.2 mm larger than the width of the circuit and the fuse. In this way, the preset circuit and fuse part of the metal foil is bonded to the PET silicone film before cutting to form the circuit and fuse so as to avoid misalignment, deformation, or even damage of the metal foil during the cutting process.

In a preferred solution of the present disclosure, in the step S1, the PET silicone film features an original film with a thickness of 0.065-0.075 mm, an adhesive with a thickness of 0.02-0.025 mm, and a peeling force of 700-800 G.

In a preferred solution of the present disclosure, the thickness (a sum of the original film thickness and the release adhesive thickness) of the release film is 0.6-0.8 times the thickness of the metal foil.

In a preferred solution of the present disclosure, the release film is a single-sided adhesive release film, with a single-sided adhesive side facing downwards and contacting the metal foil.

In a preferred solution of the present disclosure, the circuit and fuse fabrication process for the FPCB further includes: flattening/shaping, by upper and lower steel rollers, the circuit and the fuse retained on the release film side of the PET silicone film, thereby flattening/shaping the circuit and the fuse on the metal foil.

In a preferred solution of the present disclosure, the circuit and fuse fabrication process for the FPCB further includes: heating and bonding, by the upper rubber roller, the lower steel roller, and upper and lower heating rollers, a thermoset adhesive film onto the PET silicone film, where the PET silicone film is located at a bottom of the thermoset adhesive film, and the heating rollers heat 100-140° C.;
heating and bonding, by the upper rubber roller, the lower steel roller, and the upper and lower heating rollers, the thermoset adhesive film onto the metal foil with the circuit and the fuse, where the thermoset adhesive film is located at a bottom of the release film side of the PET silicone film;
removing the PET silicone film with the release film side together with the release film;
performing, after removing the PET silicone film and the release film, solder mask opening on the metal foil with the circuit and the fuse; and heating and pressing, by the upper and lower heating rollers, the thermoset adhesive film; and
removing the PET silicone film at the bottom of the thermoset adhesive film together with a solder waste.

In a preferred solution of the present disclosure, the thermoset adhesive film is a polyimide (PI) thermoset adhesive film or PET thermoset adhesive film, with a thickness of 0.05-0.15 mm.

The metal foil suitable for the process of the present disclosure includes one or more of the group consisting of copper foil (pure copper foil), aluminum foil, constantan foil, aludirome foil, stainless steel foil, brass foil, gold foil, nickel foil, iron foil, cupronickel foil, silver foil, manganin foil, nichrome foil, Ni/Al foil.

In a preferred solution of the present disclosure, the adhesive of the PET silicone film includes a high-viscosity agent.

In the circuit and fuse fabrication process of the FPCB provided by the present disclosure, the PET silicone film with specific parameters/release film with specific parameters is mainly used. The preset circuit line and fuse line are formed by cutting at a corresponding part of the release film to form a concave reserved position for the circuit line and the fuse line. The metal foil is pressed onto the release film side, and the line part of the metal foil is recessed into the reserved position for the circuit line and the fuse line, and bonded to the high-viscosity PET silicone film. The metal copper foil bonded to the high-viscosity PET silicone film is cut to obtain a regular conductive line and fuse. The conductive line and fuse all fall into the reserved position for the circuit line and the fuse line, and the thickness of the conductive line and fuse is greater than that of the release film, forming sufficient interlayer spacing. Even if the release film and the metal foil waste are quickly peeled off, it is not easy to cause misalignment and deformation of the conductive line and fuse. Therefore, the process of the present disclosure has the advantages of high yield and high efficiency, and is particularly suitable for the preparation of fuses with complex structures and small thickness/width.

### BRIEF DESCRIPTION OF THE DRAWINGS

FIG. 1 is a schematic diagram of an existing circuit and fuse fabrication process for a flexible printed circuit board (FPCB) according to the background art;

FIG. 2 is a flowchart of a circuit and fuse fabrication process for the FPCB according to the present disclosure;

FIG. 3 is a schematic diagram showing that a release film is bonded onto a bottom of a polyethylene terephthalate (PET) silicone film;

FIG. 4 is a schematic diagram of cutting the release film;

FIG. 5 is a schematic diagram after the release film is removed;

FIG. 6 is a schematic diagram of pressing and bonding a metal foil onto a release film side of the PET silicone film;

FIG. 7 is a schematic diagram of cutting to form a circuit and a fuse;

FIG. 8 is a schematic diagram of the fuse;

FIG. 9 is a schematic diagram of bonding a PET silicone film onto a bottom of the metal foil where the circuit and the fuse are formed by cutting;

FIG. 10 is a schematic diagram of retaining the circuit and fuse formed by cutting on the release film side of the PET silicone film;

FIG. 11 is a schematic diagram of flattening the circuit and the fuse on the metal foil;

FIG. 12 is a schematic diagram of heating and bonding a thermoset adhesive film 17 onto the metal foil with the circuit and the fuse; and

FIG. 13 is a schematic diagram of removing the PET silicone film at the bottom of the thermoset adhesive film and a solder waste.

### DETAILED DESCRIPTION OF THE EMBODIMENTS

The technical solutions in the embodiments of the present disclosure are described below clearly and completely with reference to the drawings. Apparently, the described embodiments are merely some rather than all of the embodiments of the present disclosure. All other embodiments obtained by those of ordinary skill in the art based on the embodiments of the present disclosure without creative efforts should fall within the protection scope of the present disclosure.

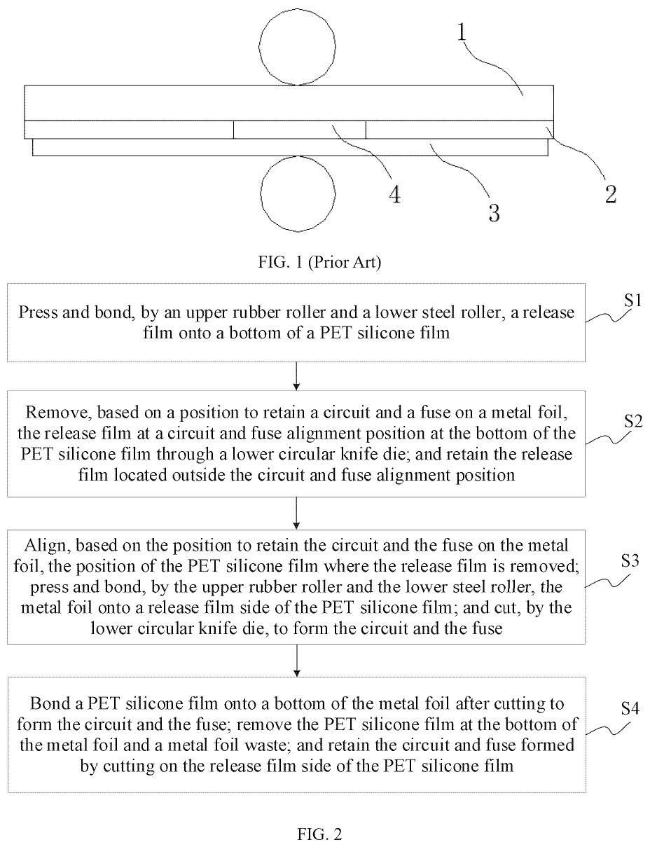

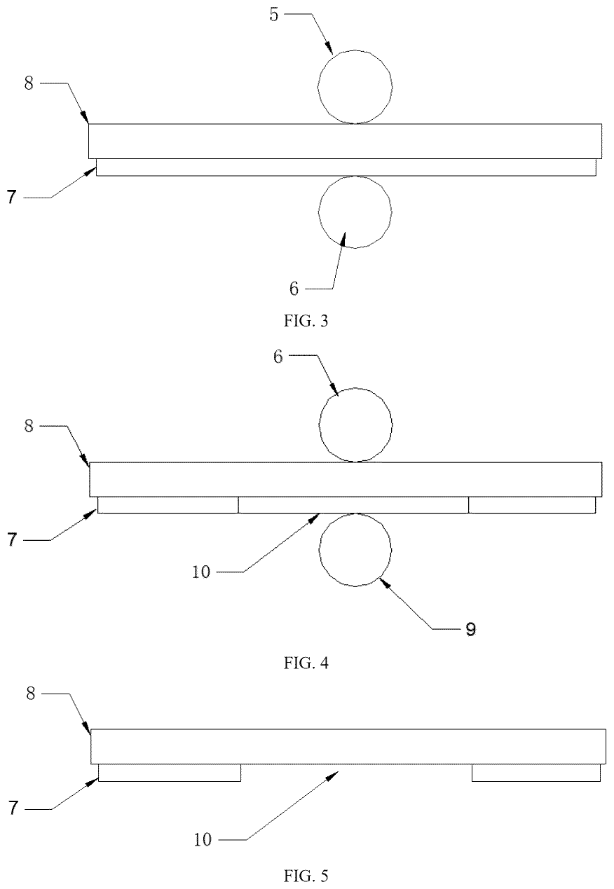

As shown in FIG. 2, a circuit and fuse fabrication process for a flexible printed circuit board (FPCB) includes the following steps.
S1. Upper rubber roller 5 and lower steel roller 6 press and bond release film 7 featuring an original film with a thickness of 0.02-0.08 mm, a release adhesive with a thickness of 0.001-0.005 mm, and a peeling force of 1-10 G onto a bottom of PET silicone film 8 featuring an original film with a thickness of 0.06-0.08 mm, an adhesive with a thickness of 0.01-0.03 mm, and a peeling force of 600-1,000 G, as shown in FIG. 3.

The PET silicone film is a PET silicone film with a high-viscosity agent. The PET silicone film with the high-viscosity agent can be bonded to the release film and then to a metal foil, ensuring a more stable effect. In addition, the PET silicone film features an original film with a thickness of 0.065-0.075 mm, an adhesive with a thickness of 0.02-0.025 mm, and a peeling force of 700-800 G. The original film can bond well with the release film, providing stable support for cutting the width of the release film, which is crucial for improving the yield of the entire process. Furthermore, the release film is a single-sided adhesive release film, with a single-sided adhesive side facing downwards and contacting the metal foil and a non-adhesive side bonded with the PET silicone film, making it easy to completely remove the release film after subsequent hot pressing.
S2. Based on a position to retain a circuit and a fuse on a metal foil with a thickness of 0.03-0.12 mm, the release film at a circuit and fuse alignment position at the bottom of the PET silicone film is cut through lower circular knife die 9. A width of the removed release film 10 is 0.1-0.2 mm larger than a width of the circuit and the fuse, and the release film located outside the circuit and fuse alignment position is retained, as shown in FIGS. 4 and 5.

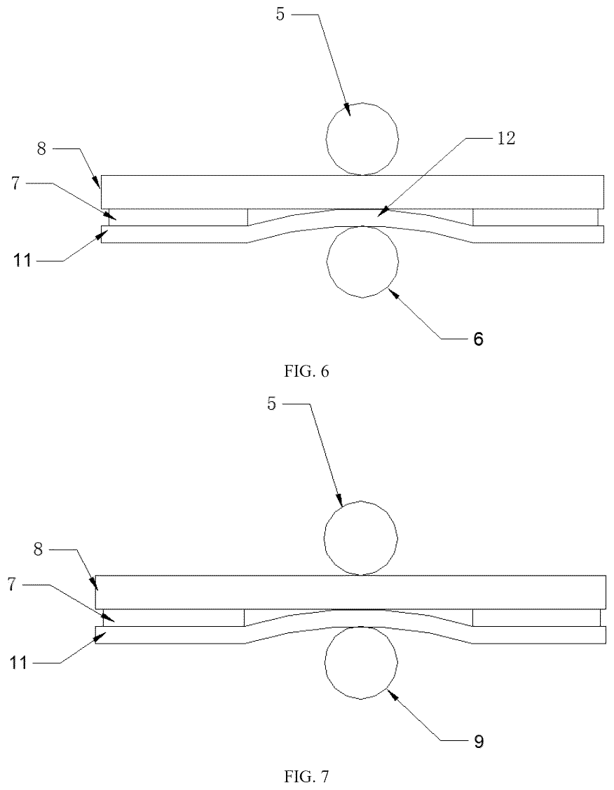

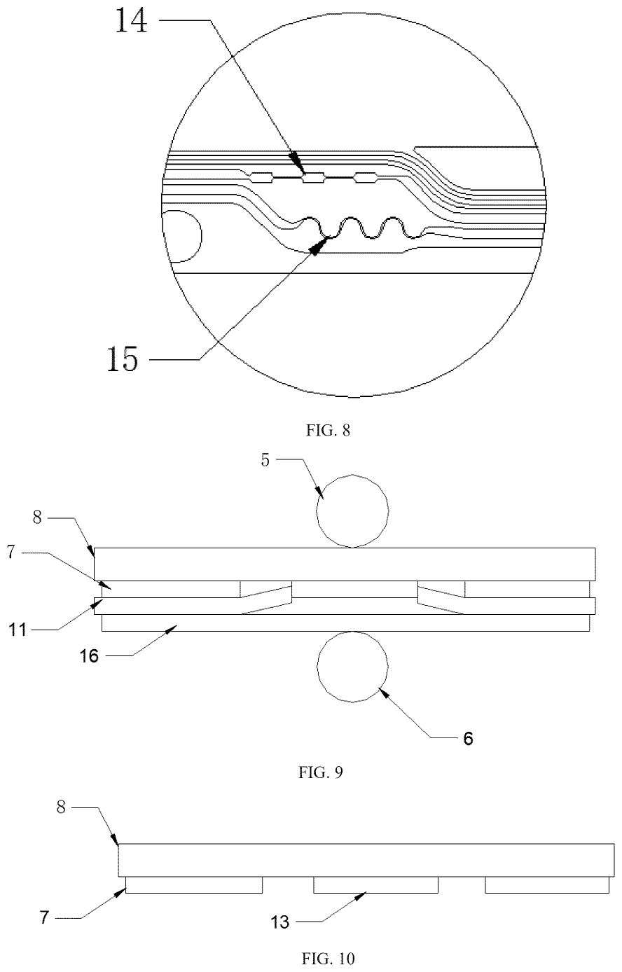

When the release film is cut, the width of the cutting position is 0.1-0.2 mm larger than the width of the circuit and the fuse, making it easier for the circuit and fuse to be embedded in the concave reserved position of the circuit and fuse wire on the metal foil, thereby achieving convenient operation. In addition, an experiment has shown that when the release film has a thickness that is 0.6-0.8 times the thickness of the metal foil, peeling off the release adhesive and the metal foil waste is less likely to touch the circuit and fuse, thereby improving the yield.
S3. Position 12 to retain the circuit and the fuse on the metal foil 11 is aligned with the position of the PET silicone film where the release film is removed, and the upper rubber roller and the lower steel roller press and bond the metal foil onto a release film side of the PET silicone film, as shown in FIG. 6. The circuit and fuse are formed by cutting by the lower circular knife die 9, as shown in FIG. 7. The fuse includes bead-shaped fuse 14 and curved fuse 15, as shown in FIG. 8. The bead-shaped fuse is formed by bead-shaped metal foils that are connected in series. A connecting line of each of the bead-shaped metal foils has a line width of 0.12-0.18 mm. The curved fuse has a line width of 0.12-0.18 mm.

In addition, the fuse includes but is not limited to the bead-shaped fuse and the curved fuse. The width of the connecting line of each bead-shaped copper foil is 0.12-0.18 mm. The line width of the curved fuse is 0.12-0.18 mm. In this way, when a short circuit or excessive current occurs, the fuse can be blown in a short time to protect other circuits.

The metal foil is made of a double-sided polished material with a surface dyne value of >36, which enhances the surface adhesion of the metal foil and facilitates the bonding of the release film to the metal foil.
S4. PET silicone film 16 is bonded onto the bottom of the metal foil after the circuit and the fuse are formed by cutting, as shown in FIG. 9. The PET silicone film at the bottom of the metal foil and the metal foil waste are removed, and the removed circuit and fuse 13 are retained on the release film side of the PET silicone film, as shown in FIG. 10.

The metal foil suitable for the process of the present disclosure includes copper foil, aluminum foil, constantan foil, aludirome foil, stainless steel foil, brass foil, gold foil, nickel foil, iron foil, cupronickel foil, silver foil, manganin foil, nichrome foil, Ni/Al foil, etc. The metal foil can also be a combination of multiple foils, depending on the material required for the circuit and fuse.

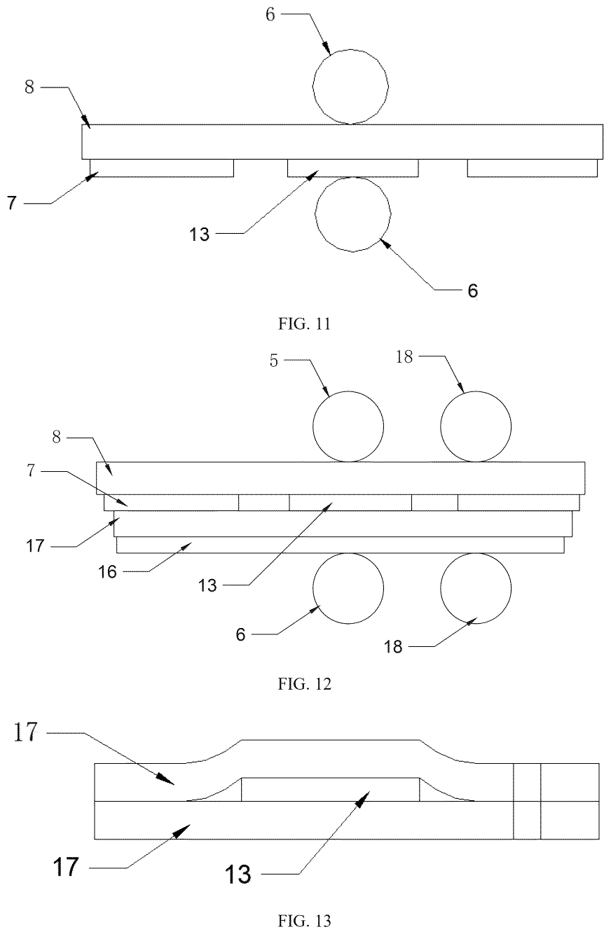

For the circuit and the fuse retained on the release film side of the PET silicone film, the circuit and the fuse on the metal foil are flattened/shaped by upper and lower steel rollers to make the circuit and fuse flat on the metal foil, as shown in FIG. 11, providing convenience for subsequent processing.

A thermoset adhesive film 17 is heated and bonded onto the PET silicone film 16 through the upper rubber roller, the lower steel roller, and upper and lower heating rollers. The PET silicone film 16 is located at a bottom of the thermoset adhesive film 17. On the flattened/shaped metal foil, the thermoset adhesive film 17 is heated and bonded to the metal foil with the circuit and the fuse through the upper rubber roller, the lower steel roller, and the upper and lower heating rollers 18. The thermoset adhesive film is located at the bottom of the release film side of the PET silicone film 8, as shown in FIG. 12. The PET silicone film with the release film side is removed together with the release film. After the PET silicone film and the release film are removed, solder mask opening is performed on the metal foil with the circuit and the fuse. The thermoset adhesive film is heated and pressed through the upper and lower heating rollers. The PET silicone film at the bottom of the thermoset adhesive film and a solder waste are removed, as shown in FIG. 13. Thus, the circuit and fuse are covered and protected, facilitating the subsequent production of the FPCB using the metal foil. The PET silicone film at the bottom of the thermoset adhesive film is also a PET silicone film with a high-viscosity agent. The PET silicone film has a thickness of 0.06 mm and a peeling force of 10-80 G. The thermoset adhesive film is a polyimide (PI) thermoset adhesive film or PET thermoset adhesive film, with a thickness of 0.05-0.15 mm. An acrylic film with a thickness of 0.05 mm and a peeling force of 1-20 G can be selected to prevent deformation during product through-hole peeling. Furthermore, in the present disclosure, the parameters of the circuit and fuse fabrication process of the FPCB are adjustable to prepare the product, and various tests are as follows.

Regarding yield, based on processes of an embodiment and a comparative example, less than 1,000 circuits are fabricated. Whether the circuit and fuse are displaced and/or deformed is observed and recorded, the deviations between the circuit and fuse and the design are observed, and the yield is calculated.

Key parameters and test results in the processes of Embodiment (A) and Comparative Example (B) are shown in the table below.

| | | A1 | A2 | A3 | A4 | A5 | A6 |
|---|---|---|---|---|---|---|---|
| S1 | Thickness of copper foil, mm | 0.05 | 0.10 | 0.08 | 0.08 | 0.08 | 0.08 |
| | Original film thickness of | 0.03 | 0.7 | 0.02 | 0.045 | 0.06 | 0.07 |
| | release film, mm | | | | | | |
| | Thickness of release | 2 | 3 | 5 | 4 | 2 | 3 |
| | adhesive, μm | | | | | | |
| | Peeling force, G | 5 | 8 | 3 | 3 | 3 | 3 |
| | Original film thickness of | 0.06 | 0.08 | 0.08 | 0.08 | 0.08 | 0.08 |
| | PET, mm | | | | | | |
| | Adhesive thickness of PET | 0.02 | 0.03 | 0.03 | 0.03 | 0.03 | 0.03 |
| | film, mm | | | | | | |
| | Peeling force, G | 800 | 1000 | 1000 | 1000 | 1000 | 1000 |
| S2 | Circular knife die, teeth | 100 | 200 | 150 | 150 | 150 | 150 |
| | Difference between width of | 0.1 | 0.2 | 0.2 | 0.2 | 0.2 | 0.2 |
| | cut release film and width of | | | | | | |
| | corresponding circuit | | | | | | |
| | and fuse, mm | | | | | | |

| | | | | | | |
|---|---|---|---|---|---|---|
| Yield, % | 90.3 | 91.7 | 88.5 | 90.8 | 91.4 | 89.1 |

| | | A7 | A8 | A9 | A10 |
|---|---|---|---|---|---|
| S1 | Thickness of copper foil, mm | 0.08 | 0.08 | 0.08 | 0.08 |
| | Original film thickness of release | 0.06 | 0.06 | 0.06 | 0.06 |
| | film, mm | | | | |
| | Thickness of release adhesive, μm | 2 | 2 | 2 | 2 |
| | Peeling force, G | 3 | 3 | 3 | 3 |
| | Original film thickness of PET, mm | 0.065 | 0.075 | 0.06 | 0.08 |
| | Adhesive thickness of PET film, mm | 0.025 | 0.02 | 0.01 | 0.03 |
| | Peeling force, G | 700 | 800 | 600 | 1000 |
| S2 | Circular knife die, teeth | 150 | 150 | 150 | 150 |
| | Difference between width of cut | 0.2 | 0.2 | 0.2 | 0.1 |
| | release film and width of | | | | |
| | corresponding circuit and fuse, mm | | | | |

| | | | | |
|---|---|---|---|---|
| Yield, % | 92.4 | 91.9 | 87.4 | 91.0 |

| | | B1 | B2 | B3 | B4 | B5 |
|---|---|---|---|---|---|---|
| S1 | Thickness of copper foil, mm | 0.08 | 0.08 | 0.08 | 0.08 | 0.08 |
| | Original film thickness of | 0.08 | 0.10 | 0.06 | 0.06 | 0.06 |
| | release film, mm | | | | | |
| | Thickness of release | 2 | 2 | 10 | 2 | 2 |
| | adhesive, μm | | | | | |
| | Peeling force, G | 3 | 3 | 30 | 3 | 3 |
| | Original film thickness of | 0.065 | 0.065 | 0.065 | 0.065 | 0.065 |
| | PET, mm | | | | | |
| | Adhesive thickness of | 0.025 | 0.025 | 0.025 | 0.025 | 0.025 |
| | PET film, mm | | | | | |
| | Peeling force, G | 700 | 700 | 700 | 400 | 1500 |
| S2 | Circular knife die, teeth | 150 | 150 | 150 | 150 | 150 |
| | Difference between width of | 0.2 | 0.2 | 0.2 | 0.2 | 0.2 |
| | cut release film and width of | | | | | |
| | corresponding circuit | | | | | |
| | and fuse, mm | | | | | |

| | | | | | |
|---|---|---|---|---|---|
| Yield, % | 77.4 | 74.3 | 81.1 | 77.6 | 82.4 |

| | | B6 | B7 | B8 | B9 | B10 |
|---|---|---|---|---|---|---|
| S1 | Thickness of copper foil, mm | 0.08 | 0.08 | 0.08 | 0.08 | 0.08 |
| | Original film thickness of | 0.06 | 0.06 | 0.06 | 0.06 | 0.06 |
| | release film, mm | | | | | |
| | Thickness of release | 2 | 2 | 2 | 2 | 2 |
| | adhesive, μm | | | | | |
| | Peeling force, G | 3 | 3 | 3 | 3 | 3 |
| | Original film thickness | 0.065 | 0.065 | 0.045 | 0.065 | 0.065 |
| | of PET, mm | | | | | |
| | Adhesive thickness of | 0.025 | 0.025 | 0.025 | 0.040 | 0.005 |
| | PET film, mm | | | | | |
| | Peeling force, G | 700 | 700 | 700 | 700 | 700 |
| S2 | Circular knife die, teeth | 150 | 150 | 150 | 150 | 150 |
| | Difference between width of | 0.05 | 0.25 | 0.2 | 0.2 | 0.2 |
| | cut release film and | | | | | |
| | width of corresponding | | | | | |
| | circuit and fuse, mm | | | | | |

| | | | | | |
|---|---|---|---|---|---|
| Yield, % | 75.4 | 77.3 | 79.7 | 81.4 | 81.2 |

From the above test results, it can be seen that the products made through the circuit and fuse fabrication process of the FPCB provided by the present disclosure have the advantages of high yield and efficiency, and the circuit and fuse fabrication process is particularly suitable for the fabrication of fuses with complex structures and small thickness/width.

Specifically, according to A5/A7-A9, a higher yield is realized by choosing the PET silicone film of the preferred parameters.

According to A3-A6, the thickness of the release film that is 0.6-0.8 times that of the metal foil corresponds to a higher yield.

According to B1/B2, when the thickness of the release film is greater than or equal to the thickness of the metal foil, it is impossible to achieve a staggered structure, which will damage the circuit and fuse structure during cutting and peeling of the waste, resulting in a decrease in the yield.

According to B3, when the thickness of the release adhesive is too large and the peeling force is too large, it is prone to damage the circuit and the fuse during peeling, resulting in lower yield.

According to B4, if the peeling force of the PET silicone film is too small, it will cause the metal foil to slide during the cutting process, resulting in misalignment of the circuit cutting.

According to B5, if the peeling force of PET silicone film is too large, it will also cause a decrease in the yield.

According to B6/B7, if the difference between the width of the removed release film and the width of the corresponding circuit and fuse is not within the scope of the present disclosure, it will result in non-compliant cutting of the circuit and fuse.

According to B8, if the original film thickness of the PET silicone film is too small, the support is insufficient, resulting in a low product yield.

According to B9, if the adhesive thickness of the PET silicone film is too large, it will cause slight displacement of the removed circuit during the cutting process, resulting in a decrease in the yield.

According to B10, if the adhesive thickness of the PET silicone film is too small, it is easy to damage the original film of the PET silicone film during the cutting process, resulting in a decrease in strength and a decrease in the yield.

The detailed solutions of the present disclosure are described through the above embodiments, but the present disclosure is not limited to the above detailed solutions, that is, it does not mean that the present disclosure must rely on the above detailed solutions to be implemented. Those skilled in the art should understand that any improvement to the present disclosure, equivalent replacement of each raw material of the product of the present disclosure, addition of auxiliary ingredients, selection of specific methods, and the like all fall within the protection scope and disclosure scope of the present disclosure.

What is claimed is:

1. A circuit and fuse fabrication process for a flexible printed circuit board (FPCB), comprising the following steps:
S1: pressing and bonding, by an upper rubber roller and a lower steel roller, a release film featuring an original film with a thickness of 0.02-0.08 mm, a release adhesive with a thickness of 0.001-0.005 mm, and a peeling force of 1-10 G onto a bottom of a first polyethylene terephthalate (PET) silicone film featuring an original film with a thickness of 0.06-0.08 mm, an adhesive with a thickness of 0.01-0.03 mm, and a peeling force of 600-1,000 G;
S2: removing, based on a position to retain a circuit and a fuse on a metal foil with a thickness of 0.03-0.12 mm, the release film at a circuit and fuse alignment position at the bottom of the first PET silicone film through a lower circular knife die, wherein a width of the removed release film is 0.1-0.2 mm larger than a width of the circuit and the fuse; and retaining the release film located outside the circuit and fuse alignment position;
S3: aligning, based on the position to retain the circuit and the fuse on the metal foil, the position of the first PET silicone film where the release film is removed; pressing and bonding, by the upper rubber roller and the lower steel roller, the metal foil onto a release film side of the first PET silicone film; and cutting, by the lower circular knife die, to form the circuit and the fuse; and
S4: bonding a second PET silicone film onto a bottom of the metal foil after cutting to form the circuit and the fuse; removing the second PET silicone film at the bottom of the metal foil and a metal foil waste; and retaining the circuit and fuse formed by cutting on the release film side of the first PET silicone film.

2. The circuit and fuse fabrication process for the FPCB according to claim 1, wherein the fuse comprises a bead-shaped fuse and/or a curved fuse; the bead-shaped fuse is formed by bead-shaped metal foils that are connected in series; a connecting line of each of the bead-shaped metal foils has a line width of 0.12-0.18 mm; and the curved fuse has a line width of 0.12-0.18 mm.

3. The circuit and fuse fabrication process for the FPCB according to claim 1, wherein in the step S1, the first PET silicone film features an original film with a thickness of 0.065-0.075 mm, an adhesive with a thickness of 0.02-0.025 mm, and a peeling force of 700-800 G.

4. The circuit and fuse fabrication process for the FPCB according to claim 1, wherein the release film has a thickness that is 0.6-0.8 times the thickness of the metal foil.

5. The circuit and fuse fabrication process for the FPCB according to claim 1, wherein the release film is a single-sided adhesive release film, with a single-sided adhesive side facing downwards and contacting the metal foil.

6. The circuit and fuse fabrication process for the FPCB according to claim 1, further comprising: flattening/shaping, by upper and lower steel rollers, the circuit and the fuse retained on the release film side of the first PET silicone film, wherein the circuit and the fuse on the metal foil are flattened/shaped.

7. The circuit and fuse fabrication process for the FPCB according to claim 6, further comprising: heating and bonding, by the upper rubber roller, the lower steel roller, and upper and lower heating rollers, a thermoset adhesive film onto the third PET silicone film, wherein the third PET silicone film is located at a bottom of the thermoset adhesive film;
heating and bonding, by the upper rubber roller, the lower steel roller, and the upper and lower heating rollers, the thermoset adhesive film onto the metal foil with the circuit and the fuse, wherein the thermoset adhesive film is located at a bottom of the release film side of the first PET silicone film;
removing the first PET silicone film with the release film side together with the release film;
performing, after removing the first PET silicone film and the release film, solder mask opening on the metal foil with the circuit and the fuse; and heating and pressing, by the upper and lower heating rollers, the thermoset adhesive film; and
removing the third PET silicone film at the bottom of the thermoset adhesive film together with a solder waste.

8. The circuit and fuse fabrication process for the FPCB according to claim 7, wherein the thermoset adhesive film is a polyimide (PI) thermoset adhesive film or PET thermoset adhesive film, with a thickness of 0.05-0.15 mm.

9. The circuit and fuse fabrication process for the FPCB according to claim 1, wherein the metal foil comprises at least one of the group consisting of copper foil, aluminum foil, constantan foil, aludirome foil, stainless steel foil, brass foil, gold foil, nickel foil, iron foil, cupronickel foil, silver foil, manganin foil, nichrome foil, and Ni/Al foil.

10. The circuit and fuse fabrication process for the FPCB according to claim 1, wherein the adhesive of the first PET silicone film comprises a high-viscosity agent.

11. The circuit and fuse fabrication process for the FPCB according to claim 2, wherein the release film is a single-sided adhesive release film, with a single-sided adhesive side facing downwards and contacting the metal foil.

12. The circuit and fuse fabrication process for the FPCB according to claim 3, wherein the release film is a single-sided adhesive release film, with a single-sided adhesive side facing downwards and contacting the metal foil.

13. The circuit and fuse fabrication process for the FPCB according to claim 2, further comprising: flattening/shaping, by upper and lower steel rollers, the circuit and the fuse retained on the release film side of the first PET silicone film, wherein the circuit and the fuse on the metal foil are flattened/shaped.

14. The circuit and fuse fabrication process for the FPCB according to claim 3, further comprising: flattening/shaping, by upper and lower steel rollers, the circuit and the fuse retained on the release film side of the first PET silicone film, wherein the circuit and the fuse on the metal foil are flattened/shaped.

15. The circuit and fuse fabrication process for the FPCB according to claim 13, further comprising: heating and bonding, by the upper rubber roller, the lower steel roller, and upper and lower heating rollers, a thermoset adhesive film onto the third PET silicone film, wherein the third PET silicone film is located at a bottom of the thermoset adhesive film;
heating and bonding, by the upper rubber roller, the lower steel roller, and the upper and lower heating rollers, the thermoset adhesive film onto the metal foil with the circuit and the fuse, wherein the thermoset adhesive film is located at a bottom of the release film side of the first PET silicone film;
removing the first PET silicone film with the release film side together with the release film;
performing, after removing the first PET silicone film and the release film, solder mask opening on the metal foil with the circuit and the fuse; and heating and pressing, by the upper and lower heating rollers, the thermoset adhesive film; and
removing the third PET silicone film at the bottom of the thermoset adhesive film together with a solder waste.

16. The circuit and fuse fabrication process for the FPCB according to claim 14, further comprising: heating and bonding, by the upper rubber roller, the lower steel roller, and upper and lower heating rollers, a thermoset adhesive film onto the third PET silicone film, wherein the third PET silicone film is located at a bottom of the thermoset adhesive film;
heating and bonding, by the upper rubber roller, the lower steel roller, and the upper and lower heating rollers, the thermoset adhesive film onto the metal foil with the circuit and the fuse, wherein the thermoset adhesive film is located at a bottom of the release film side of the first PET silicone film;
removing the first PET silicone film with the release film side together with the release film;
performing, after removing the first PET silicone film and the release film, solder mask opening on the metal foil with the circuit and the fuse; and heating and pressing, by the upper and lower heating rollers, the thermoset adhesive film; and
removing the third PET silicone film at the bottom of the thermoset adhesive film together with a solder waste.

17. The circuit and fuse fabrication process for the FPCB according to claim 15, wherein the thermoset adhesive film is a polyimide (PI) thermoset adhesive film or PET thermoset adhesive film, with a thickness of 0.05-0.15 mm.

18. The circuit and fuse fabrication process for the FPCB according to claim 16, wherein the thermoset adhesive film is a polyimide (PI) thermoset adhesive film or PET thermoset adhesive film, with a thickness of 0.05-0.15 mm.
